(19) United States
(12) Patent Application Publication
(10) Pub. No.: US 2003/0166314 A1
(43) Pub. Date: Sep. 4, 2003

(54) Resin encapsulated BGA-type semiconductor device

(76) Inventors: Yoshihiro Ono, Tokyo (JP); Takehiko Maeda, Tokyo (JP)

Correspondence Address: Norman P. Soloway, HAYES SOLOWAY P.C., 130 W. Cushing Street, Tucson, AZ, 85701, US

(21) Appl. No.: 10/412,001

(22) Filed: Apr. 11, 2003

Related U.S. Application Data
(62) Division of application No. 09/940,249, filed on Aug. 27, 2001.

(30) Foreign Application Priority Data
Aug. 29, 2000 (JP) 2000-258423

(51) Int. Cl. H01L 21/58

(52) U.S. Cl. 438/125; 438/121; 438/124; 438/126

(57) ABSTRACT

A method for fabricating a resin-encapsulated semiconductor device includes the steps of consecutively forming a first interconnect pattern, a dielectric film and a second interconnect pattern on a metallic plate, mounting a semiconductor chip on the dielectric film, connecting chip electrodes of the semiconductor chip to the second interconnect pattern, encapsulating the semiconductor chip on the first dielectric film, removing the metallic plate selectively from the first interconnect pattern, and forming a plurality of metallic bumps on the exposed bottom surface of the first interconnect pattern.

### BACKGROUND OF THE INVENTION

(a) Field of the Invention

The present invention relates to resin encapsulated BGA-type semiconductor devices and fabrication methods thereof and, more specifically, to a semiconductor structure suitable for reducing a thickness and an occupied area of the semiconductor devices.

(b) Description of the Prior Art

BGA-type semiconductor devices have become popular in recent years because of smaller dimensions thereof. FIG. 1 shows the structure of a conventional resin encapsulated BGA-type semiconductor device. A semiconductor chip 41 is mounted on an interposer substrate 42 at the central area thereof, and the bottom of the semiconductor chip 41 is fixed onto the interposer substrate 42 with an adhesive 43. The interposer substrate 42 is made of polyimide, glass-epoxy or an organic dielectric material, such as BT resin. On the interposer substrate 42, an interconnect pattern 44, which is made of a metallic material such as copper, is formed. The adhesive 43 is made of materials of which the main component is a thermosetting epoxy resin.

In the above conventional BGA-type semiconductor device, the interposer substrate 42 has a two-layer structure including the organic dielectric material 45 and the interconnect pad 44, which is made of a metallic material such as copper, formed on the organic dielectric material 45. Thus, it is difficult to further reduce the thickness of the BGA-type semiconductor device having such an interposer substrate 42.

Japanese Patent Laid-Open Publication Nos. Hei. 2-240940,10-116935 and 11-195733 describe techniques for reducing the thickness of the resin interposer substrate by polishing the interposer substrate at the bottom surface thereof to solve the above problem.

The techniques described in the aforementioned publications employ a resin interposer substrate that will be removed later by polishing. Typically, in BGA-type semiconductor devices, once the geometry of a stitch section to which bonding wires are connected is determined, the location of metallic bumps that constitute external terminals is also limited to within the vicinity of the outer periphery of the stitch section. As a result, the external terminals have poor flexibility with respect to their location and it is difficult to further reduce the two-dimensional size of the electronic component and electronic apparatus that bear such a BGA-type semiconductor device.

Particularly, as the need for smaller electronic components and electronic apparatuses is growing, the arrangement of the external terminals of semiconductor devices is strongly required to have smaller pitch. The pattern pitch in the electrode pads of semiconductor chip is narrowed to some extent because of the progress in the technology of photolithography. However, a sufficient space is still needed for formation of the metallic bumps of the semiconductor chip and thus the reduction of the pitch of external terminals is not satisfactorily attained.

### SUMMARY OF THE INVENTION

It is, therefore, an object of the present invention to reduce the size of semiconductor devices, in particular the thickness and planar size thereof, by improving their structure.

Another object of the invention is to reduce the cost and size of BGA-type semiconductor devices and to improve the reliability of electronic components and electronic apparatuses having the BGA-type semiconductor devices, thereby providing flexibility in the arrangement of the external terminals.

The present invention provides a semiconductor device including a first interconnect pattern, a first dielectric film covering top and side surfaces of the first interconnect pattern and having therein through-holes, a second interconnect pattern electrically connected to the first interconnect pattern via the through-holes, a semiconductor chip having a plurality of chip electrodes and mounted on the first dielectric film, interconnect members for connecting the chip electrodes to the second interconnect patterns, an encapsulating resin for encapsulating the semiconductor chip and the interconnect members on the first dielectric film, and a second dielectric film covering a bottom surface of the first interconnect pattern.

The present invention also provides a method for fabricating a semiconductor device including the steps of forming a first interconnect pattern on a metallic plate, forming a first dielectric film having a plurality of through-holes on the first interconnect pattern, forming a second interconnect pattern on the first dielectric film, the second interconnect pattern being electrically connected to the first interconnect pattern via the through-holes, mounting a semiconductor chip having a plurality of chip electrodes on the first dielectric film, connecting the chip electrodes to the second interconnect pattern, encapsulating the semiconductor chip on the first dielectric film, removing the metallic plate from a bottom surface thereof selectively from the first interconnect pattern, and forming a second dielectric film on a bottom surface the first interconnect pattern.

The present invention also provides a method for fabricating a semiconductor device including the steps of forming a first interconnect pattern on a top surface of metallic plate, forming a second interconnect pattern on a bottom surface of a metallic plate, mounting a semiconductor chip having a plurality of chip electrodes on the top surface of the metallic plate, connecting the chip electrodes to the first interconnect pattern, encapsulating the semiconductor chip on the top surface of the metallic plate, removing the metallic plate by using the second interconnect pattern as a mask, forming a plurality of external electrodes on the second interconnect pattern, and forming a dielectric film on the second interconnect pattern and an area from which the metallic plate is removed, the dielectric film exposing therefrom the external electrodes.

In accordance with the semiconductor device of the present invention and the semiconductor device fabricated by the method of the present invention, the thickness and the two-dimensional size of the semiconductor device can be significantly reduced by incorporating the metallic plate which is removed after the semiconductor chip is mounted and encapsulated, without degrading the mechanical stability during the fabrication process.

The above and other objects, features and advantages of the present invention will be more apparent from the following description, referring to the accompanying drawings.

### BRIEF DESCRIPTION OF THE DRAWINGS

FIG. 1 is a sectional view of a conventional BGA-type semiconductor device.

FIG. 2 is a sectional view of a BGA-type semiconductor device according to a first embodiment of the present invention.

FIG. 3 is a top plan view of the first interconnect pattern shown in FIG. 2.

FIGS. 4A and 4B are a top plan views of the through-hole pattern in the first insulator film and the second interconnect pattern, respectively, shown in FIG. 2.

FIG. 5 is a bottom view of the semiconductor device of FIG. 2, showing the arrangement of metallic bumps.

FIGS. 6A to 6G are sectional views of a semiconductor device, consecutively showing the steps of a fabrication process thereof according to a fifth embodiment of the present invention..

FIG. 7 is a sectional view of a BGA-type semiconductor device according to a second embodiment of the present invention.

FIG. 8 is a sectional view of a BGA-type semiconductor device according to a third embodiment of the present invention.

FIG. 9 is a sectional view of a BGA-type semiconductor device according to a fourth embodiment of the present invention.

FIGS. 10A to 10E are sectional views a semiconductor device, consecutively showing the steps of a fabrication process thereof according to a sixth embodiment of the present invention.

FIGS. 11A to 11E are sectional views a semiconductor device, consecutively showing the steps of a fabrication process thereof according to a seventh embodiment of the present invention.

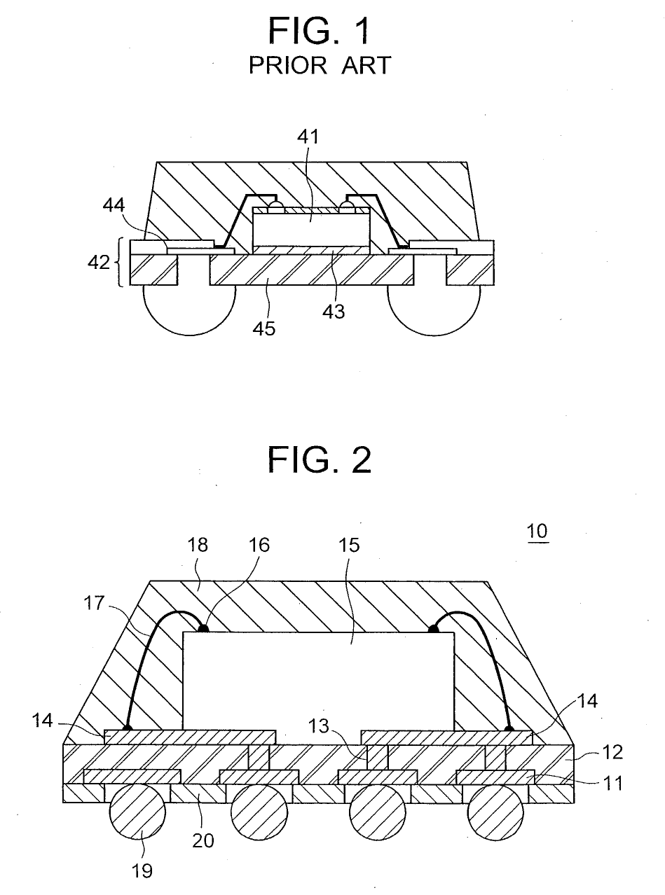

### DESCRIPTION OF THE PREFERRED EMBODIMENTS

Now, the present invention will be described based on the embodiments thereof with reference to the accompanying drawings, wherein similar constituent elements are designated by similar reference numerals.

Referring to FIG. 2, a semiconductor device according to a first embodiment of the present invention has a first interconnect pattern 11, and a first dielectric layer 12 covering top and side surfaces of the first interconnect pattern 11. A second interconnect pattern 14 is formed on the first dielectric layer 12 and is connected to the first interconnect pattern 11 via through-holes 13 that are formed in the first dielectric layer 12 to penetrate the same. A semiconductor chip 15 is mounted on the first dielectric layer 12, and bonding wires 17 connect chip electrodes 16 formed on the semiconductor chip 15 with the second interconnect pattern 14. A encapsulating resin 18 encapsulates the semiconductor chip 15 and the bonding wires 17 on the first dielectric layer 12, and metallic bumps 19 constituting the external electrodes are formed on the bottom surface of the first interconnect pattern 11. An adhesive dielectric sheet 20 that constitutes a second dielectric layer covers the bottom surface of the first interconnect pattern 11 and exposes the bottom surface of the metallic bumps 19.

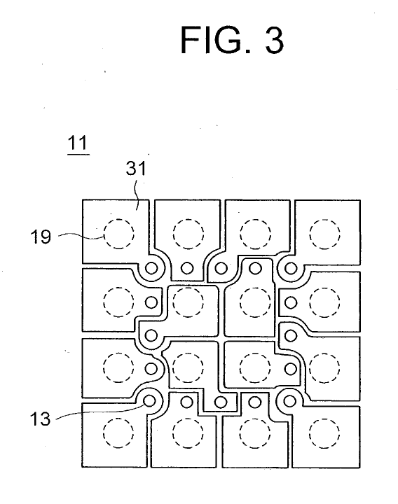

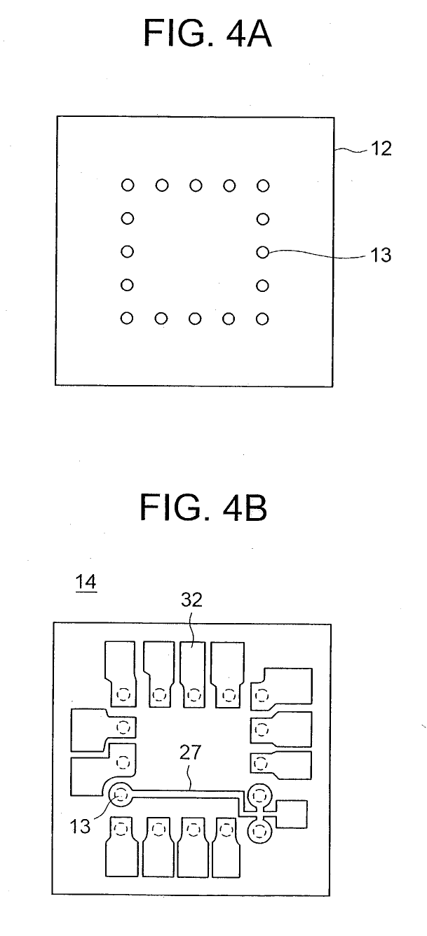

Referring to FIG. 3, there is shown an example of the first interconnect pattern in a top plan view. The first interconnect pattern 11 includes a large number of polygonal outer pads 31. Each outer pad 31 is coupled to an overlying through-hole 13, and coupled to an underlying metallic bumps 19. Since the second interconnect pattern 14 located above the through-holes 13 is formed on an area other than the area where the semiconductor chip 15 is mounted, the through-holes 13 are also formed in an area other than the area where the semiconductor chip is mounted. The metallic bumps 19 are arranged in an array on almost the whole area of the bottom surface of the semiconductor device. FIGS. 4A and 4B illustrate the location of the through-holes 13 formed in the first dielectric layer 12 and the location of the second interconnect pattern 14, respectively. Outer pads 31 of the first interconnect pattern 11 are highly flexible with respect to their location because it is sufficient that the outer pads 31 electrically connect the through-holes 13 and the metallic bumps 19. The first interconnect pattern 11 is made of a material such as Cu and 42-alloy.

In FIG. 4B, the second interconnect pattern 14 includes a large number of inner pads 32 each of which is connected to the bonding wire, and several interconnects 27 which connect the inner pads 32 with the through-holes 13. Each inner pad 32 has an inner portion located in the vicinity of the location where the semiconductor chip 15 is mounted and connected to the through-hole 13, and a stitch portion extending from the inner portion toward outside and connected to the bonding wire 17.

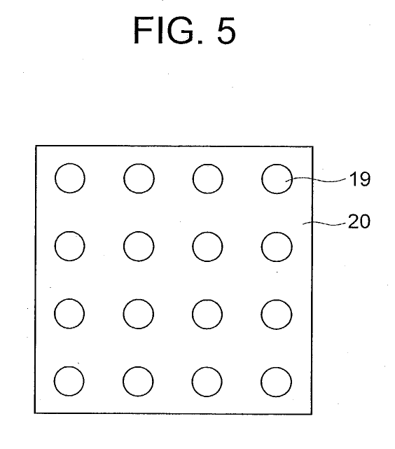

FIG. 5 illustrates the arrangement of the metallic bumps 19 formed on the bottom surface of the first interconnect pattern 11. The metallic bumps 19 are arranged in an array on almost the whole bottom surface of the semiconductor device. This arrangement is attained by separating the second interconnect pattern 14 connected to the semiconductor chip 15 and the first interconnect pattern 11 connected to the metallic bumps 19. As a result of such an arrangement of the metallic bumps 19, the flexibility in designing the semiconductor devices is improved.

The thickness of the semiconductor device according to the present embodiment can be reduced because the semiconductor device has on its bottom surface only two of thin interconnect patterns 11 and 14 and an array of metallic bumps 19.

The bonding wire 17 is made of, for example, Au, Cu, Al or Pd. Solder or conductive paste is used for connection of the bonding wires. A thermosetting polymer is preferably used as the material for the adhesive dielectric sheet 20.

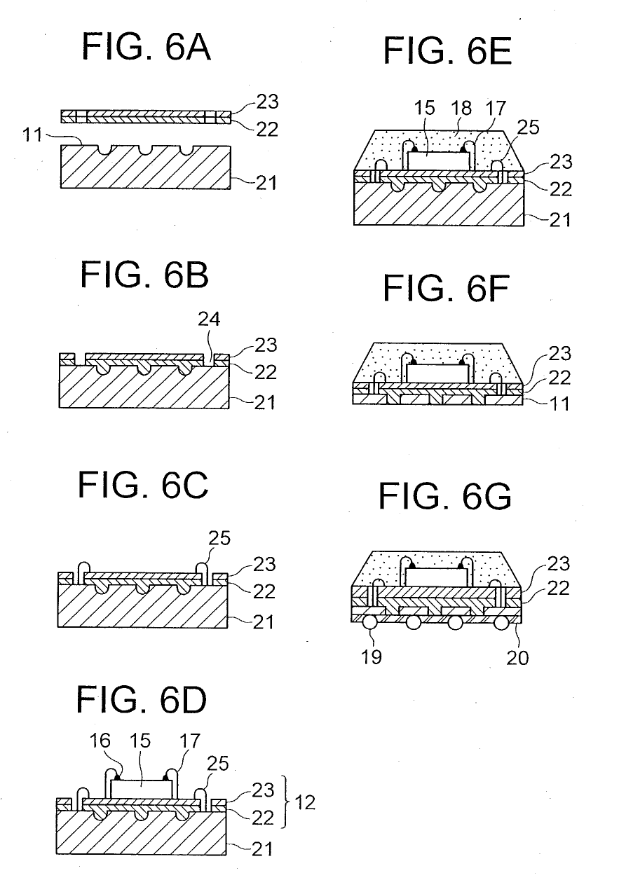

FIGS. 6A to 6G illustrate consecutive steps of a fabrication process according to an embodiment of the present invention. This fabrication process is an example of the fabrication of a modification of the semiconductor device of the first embodiment shown in FIG. 2. In this modification, the second interconnect pattern itself is multi-level interconnect pattern. In the fabrication, the first interconnect pattern 11 is first formed on the top surface of a metallic plate 21 by etching.

In FIG. 6A, a multi-level interconnect layer 23 having a plurality of interconnect layers in a dielectric substrate made of polyimide or epoxy resin is affixed with an adhesive 22 to the metallic plate 21 where the first interconnect pattern 11 is formed. A thermosetting polymeric adhesive such as polyimide is used as the adhesive 22 under the conditions of a temperature between 100° C. and 200° C. and a thrust pressure of several tens of kilograms per square centimeters (kg/cm²). The adhesive is thus adhered onto the top and side surfaces of the first interconnect pattern 12.

As shown in FIG. 6B, through-holes 24 are formed on the first interconnect pattern 11 by patterning the multi-level interconnect layer 23 using the photolithographic technique. In the photolithographic technique, for example, a photoresist may be applied and a dielectric film may be affixed prior to exposure of the photoresist. Through-holes 24 may be formed by drilling the multi-level interconnect layer 23 with a stamping die or a drill before the multi-level interconnect layer 23 is affixed onto the metallic plate 21.

Next, as shown in FIG. 6C, bonding wires 25 extending through the through-holes 24 connect the external terminals of the multi-level interconnect layer 23 with the first interconnect pattern 11. Then, the semiconductor chip 15 is mounted on the multi-level interconnect layer 23, and the chip electrodes 16 of the semiconductor chip 15 are connected to the inner electrodes of the multi-level interconnect layer 23 with the bonding wires 17, as shown in FIG. 6D.

Subsequently, as shown in FIG. 6E, the semiconductor chip 15 and the bonding wires 17 and 25 are encapsulated with the encapsulating resin 18. Thereafter, the metallic plate 21 is removed by polishing from the bottom surface thereof, as shown in FIG. 6F, leaving the interconnect pattern 11 of the metallic plate 21. The removal of the metallic plate 21 is performed by, for example, chemical-mechanical polishing (CMP) technique. Then, metallic bumps 19 are formed as external electrodes at desired positions on the first interconnect pattern 11 that is exposed by removing the metallic plate 21. Subsequently, the semiconductor device is obtained d by covering the bottom surface of the first interconnect pattern 11 with the second dielectric layer 20.

In the above embodiment, the first dielectric layer and the second interconnect pattern 14 are formed by bonding the multi-level interconnect layer 23 to the first interconnect layer 11. However, the first dielectric layer 12 and then the second interconnect pattern 14 may be formed on the metallic plate 21 in this order, as depicted in FIG. 2.

For example, the first dielectric layer 12 in the semiconductor device of the first embodiment may be formed by applying photosensitive dielectric resins such as polyimide or epoxy resin with a spin-coater. This allows the through-holes 13 to be formed by exposure and development steps. In addition, the through-holes 13 may be formed by applying an ordinary dielectric material with a spin-coater and etching the same by using a photoresist mask.

It is also possible to form the first dielectric layer 12 by the screen-printing method. In this case, a dielectric material such as urethane is affixed onto the metallic plate by squeegee and cured by high-temperature baking process or UV irradiation process. This process is conducted after a screen mask, covering the locations where the through-holes 13 are to be formed and exposing the area where the first dielectric layer 12 is to be formed, is mounted on the first interconnect pattern 11. The screen mask is composed of, for example, a wire net or metallic mesh, and a mask covering the metallic mesh.

The second interconnect pattern 14 may be formed by, for example, sputtering after the formation of the first dielectric layer 12 which has therein the through-holes 13. In this case, a resist layer is formed on the first dielectric layer 12 and then a conductive layer is formed thereon by sputtering. After a desired pattern is formed on the resist layer and the conductive layer by exposure and development thereof, Al, Ni, Cu or the like is embedded in the pattern by electrolytic plating. Thereafter, the resist layer is removed and the conductive layer made by the sputtering is removed by etching.

The second interconnect pattern 14 may be formed also by the screen-printing method using a conductive paste. Metals such as Ag and Cu may be used as the conductive paste material in this case. After a conductive paste is applied by the screen-printing method, the resin is cured by baking at a high temperature or by UV irradiation.

As methods for removing the metallic plate 21 in the present embodiment, chemical etching, mechanical grinding and mechanical peel-off techniques may be employed in addition to chemical-mechanical polishing. Among others, the mechanical peel-off technique can take an advantage of the difference in the thermal expansion coefficients between the two metal layers and the softening of either of the metal layers at high temperatures. In the chemical etching technique, for example, a metallic plate is formed by Cu or 42-alloy, and the etching liquid may be a ferric chloride solution. When a mechanical peel-off technique is employed, it is preferable that the first interconnect pattern be formed by plating on the metallic plate, and the metallic plate be peeled-off at the boundary of the plating.

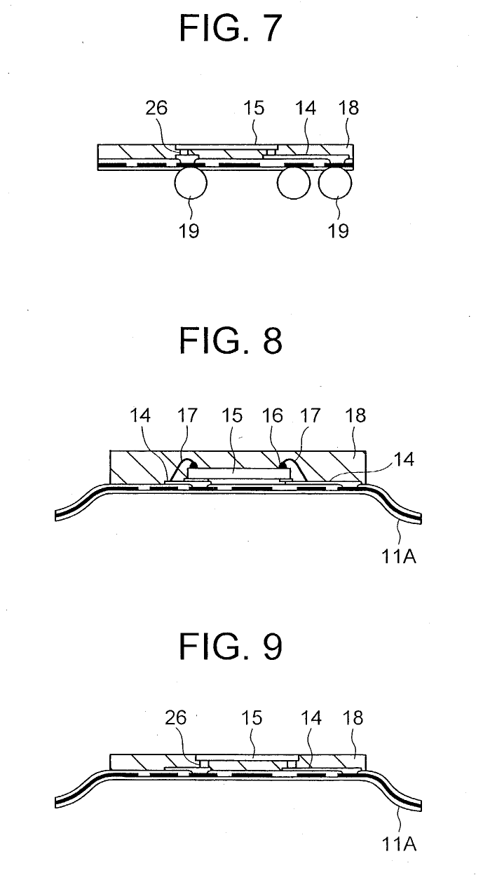

FIG. 7 illustrates a semiconductor device according to a second embodiment of the present invention. One of the differences from the first embodiment is that the chip electrode 16 of the semiconductor chip 15 in the first embodiment is replaced by a metallic bump 26 formed on the second interconnect pattern 14. Another difference is that the top of the encapsulating resin 18 and the semiconductor chip 15 are removed in the present embodiment by polishing after the semiconductor chip 15 is encapsulated with the encapsulating resin 18.

FIG. 8 illustrates a semiconductor device according to a third embodiment of the present invention. This embodiment is different from the first embodiment in that a portion of the first interconnect pattern 11 in the first embodiment is used as the external electrode 11A in the present embodiment.

FIG. 9 illustrates a semiconductor device according to a forth embodiment of the present invention. This embodiment is different from the third embodiment in that the chip electrodes of the semiconductor chip 15 in the present embodiment are connected to the second interconnect pattern 14 with metallic bumps 26.

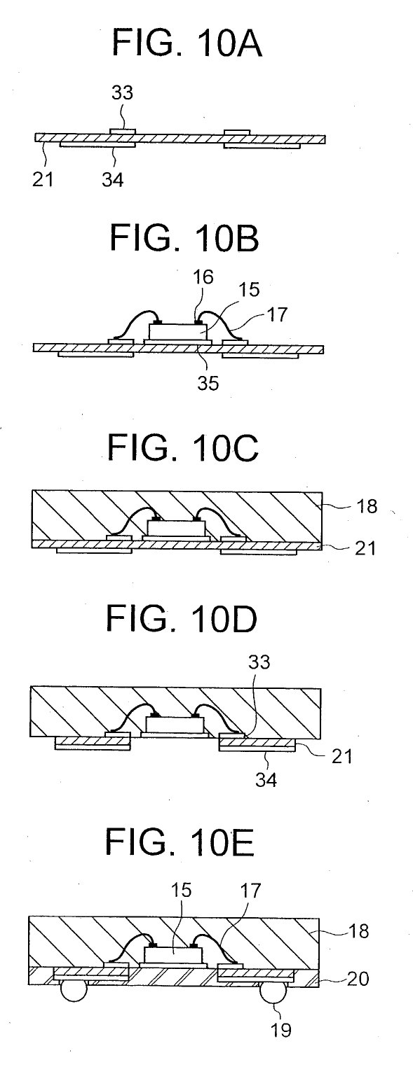

FIGS. 10A to 10E illustrate a fabrication process according to another embodiment of the present invention. In the present embodiment, a first interconnect pattern 33 made of Au and a second interconnect pattern 34 made of Au are formed, by plating, on the top surface and the bottom surface, respectively, of a metallic plate 21 made of Cu, as shown in FIG. 10A. Next, a dielectric adhesive 35 is applied onto the top surface of the metallic plate 21 and a semiconductor chip 15 is mounted thereon for bonding. As shown in FIG. 10B, the chip electrodes 16 of the semiconductor chip 15 are connected to the stitch portions of the first interconnect pattern 33 with bonding wires 17. Then, the semiconductor chip 15 and the bonding wires 17 are encapsulated on the top surface of the metallic plate 21 with the encapsulating resin 18.

Subsequently, the metallic plate 21 is selectively removed by etching using the second interconnect pattern 34 as a mask and the area of the metallic plate 21 other than the top surface of the second interconnect pattern 34 is removed, as shown in FIG. 10D. A dielectric resin that forms a dielectric layer 20 is applied onto the whole area of the bottom surface of the semiconductor device other than the area where the metallic bumps of the second interconnect pattern 34 are to be formed. As shown in FIG. 10E, metallic bumps 19 are then formed on the second interconnect pattern 34 where the dielectric layer 20 is not formed.

With respect to the semiconductor device fabricated by the above process, the metallic plate 21 remains on the top surface of the second interconnect pattern 34 as a supporting structure. Since this metallic plate 21 has a high mechanical strength, the overall mechanical strength of the semiconductor device of the present embodiment is higher than that of the conventional semiconductor device which has a tape substrate. Besides, there is an advantage in that this type of semiconductor device needs fewer components compared to the conventional semiconductor device having the three-layer structure including interconnect pattern, substrate material and interconnect pattern. In addition, the interconnect patterns 33 and 34, which are formed on the metallic plate 21 by plating, are left as the interconnect patterns in the final structure. Considering that the interconnect pattern made by plating can be formed with greater accuracy in general than that formed by other techniques, for example etching, a finer-patterned interconnect structure can be provided by the present embodiment. Also, since the above fabrication process according to the present embodiment does not involve a through-hole formation process, semiconductor devices can be manufactured with higher throughputs.

Since the first interconnect pattern 33 is formed only in the stitch portion that is used as the contact area for the chip electrode 16 of the semiconductor chip 15, and the second interconnect pattern 34 and its top metallic plate 21 are extended to cover a greater area, the arrangement of the metallic bumps 19 has more flexibility, and the overall mechanical strength of the semiconductor device is improved.

The first and second interconnect patterns are formed with, for example, Ni/Au, Au, Ag, Pd or solder plating.

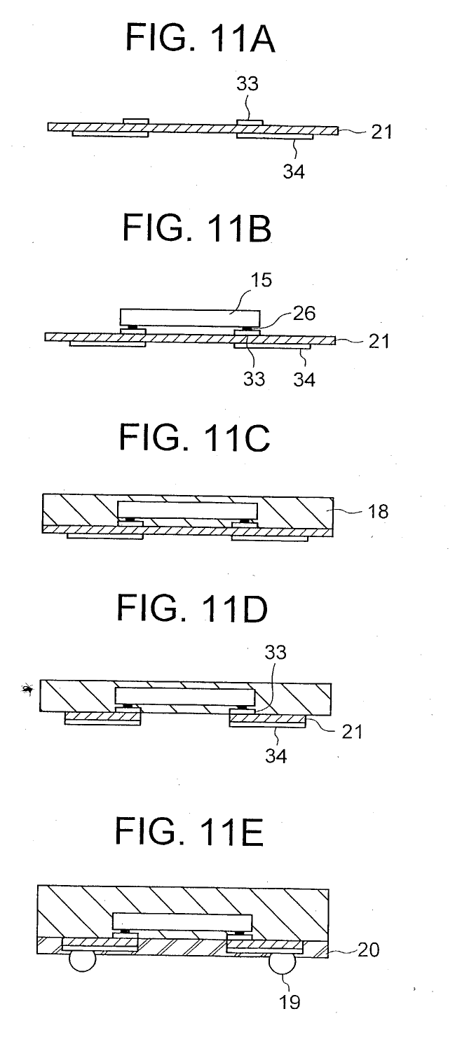

FIGS. 11A to 11E illustrate a fabrication process according to another embodiment of the present invention. In this embodiment, the first interconnect pattern 33 made of Au and the second interconnect pattern 34 made of Au are formed, by plating, on the top surface and the bottom surface, respectively, of the metallic plate 21 made of Cu, as shown in FIG. 11A. Subsequently, as shown in FIG. 11B, a semiconductor chip 15 having metallic bumps 26, namely solder bumps, on its bottom surface is bonded onto the first interconnect pattern 33 with a conductive adhesive. Then, the semiconductor chip 15 is encapsulated on the metallic plate 21 with the encapsulating resin 18.

Next, the metallic plate 21 is etched using the second interconnect pattern 34 as a mask and the area of the metallic plate 21 other than the top surface of the second interconnect pattern 34 is selectively removed, as shown in FIG. 11D. A dielectric resin that forms a dielectric layer 20 is applied to the whole area of the bottom surface of the semiconductor device other than the area where the metallic bumps 19 of the second interconnect pattern 34 are to be formed. As shown in FIG. 11E, the metallic bumps 19 are formed on the second interconnect pattern 34 where the dielectric layer 20 is not formed.

According to the fabrication method of this embodiment, the first interconnect pattern 33 requires a smaller occupied area.

Examples of the dielectric material which can be used in the present invention include polyimide, epoxy, phenol and silicone resin. Examples of the material which can be used for the interconnect pattern include Ni, Cu and Au. Conductive pastes including, for example, Ag and Cu may be used in the printing method. Examples of the material which can be used for the bonding wires include Au, Cu, Al and Pd. Examples of the material which can be used for the metallic bumps include solder, anisotropic conductive materials and conductive pastes. Examples of the adhesives which can be used include thermosetting polymeric adhesives such as polyimide and epoxy resin.

Since the above embodiments are described only for examples, the present invention is not limited to the above embodiments and various modifications or alterations can be easily made therefrom by those skilled in the art without departing from the scope of the present invention.

What is claimed is:

1. A semiconductor device comprising a first interconnect pattern, a first dielectric film covering top and side surfaces of said first interconnect pattern and having therein through-holes, a second interconnect pattern electrically connected to said first interconnect pattern via said through-holes, a semiconductor chip having a plurality of chip electrodes and mounted on said first dielectric film, interconnect members for connecting said chip electrodes to said second interconnect patterns, an encapsulating resin for encapsulating said semiconductor chip and said interconnect members on said first dielectric film, and a second dielectric film covering a bottom surface of said first interconnect pattern.

2. A semiconductor device as defined in claim 1, further comprising a plurality of external terminals formed on said bottom surface of said first interconnect pattern and exposed from said second dielectric film.

3. The semiconductor device as defined in claim 2, wherein said external terminals are metallic bumps.

4. The semiconductor device as defined in claim 1, wherein portions of said first interconnect pattern are formed as a plurality of external terminals.

5. The semiconductor device as defined in claim 1, wherein said interconnect members are metallic bumps.

6. The semiconductor device as defined in claim 1, wherein said interconnect members are bonding wires.

7. A method for fabricating a semiconductor device comprising the steps of forming a first interconnect pattern on a metallic plate, forming a first dielectric film having a plurality of through-holes on said first interconnect pattern, forming a second interconnect pattern on said first dielectric film, said second interconnect pattern being electrically connected to said first interconnect pattern via said through-holes, mounting a semiconductor chip having a plurality of chip electrodes on said first dielectric film, connecting said chip electrodes to said second interconnect pattern, encapsulating said semiconductor chip on said first dielectric film, removing said metallic plate at a bottom surface thereof selectively from said first interconnect pattern, and forming a second dielectric film on a bottom surface said first interconnect pattern.

8. The method as defined in claim 7, further comprising the steps of forming a plurality of external terminals on said first interconnect pattern.

9. The method as defined in claim 7, wherein said first interconnect pattern is formed by etching said metallic plate.

10. The method as defined in claim 9, wherein said etching is implemented by one of chemical etching, chemical mechanical etching, mechanical grinding and mechanical peeling-off.

11. The method as defined in claim 7, wherein said second dielectric film is an adhesive sheet.

12. A method for fabricating a semiconductor device comprising the steps of forming a first interconnect pattern on a top surface of metallic plate, forming a second interconnect pattern on a bottom surface of a metallic plate, mounting a semiconductor chip having a plurality of chip electrodes on said top surface of said metallic plate, connecting said chip electrodes to said first interconnect pattern, encapsulating said semiconductor chip on said top surface of said metallic plate, removing said metallic plate by using said second interconnect pattern as a mask, forming a plurality of external electrodes on said second interconnect pattern, and forming a dielectric film on said second interconnect pattern and an area from which said metallic plate is removed, said dielectric film exposing therefrom said external electrodes.

13. The method as defined in claim 12, wherein said connecting step uses metallic bumps or bonding wires.

14. The method as defined in claim 12, wherein said first interconnect pattern is formed by plating.

15. The method as defined in claim 12, wherein said metallic plate is a Cu plate and said second interconnect pattern is formed by plating.
